(19) United States
(12) Patent Application Publication
(10) Pub. No.: US 2024/0397785 A1
(43) Pub. Date: Nov. 28, 2024

(54) DISPLAY DEVICE

(71) Applicant: Samsung Display Co., Ltd., Yongin-si (KR)

(72) Inventor: BYEONGIN PARK, Yongin-si (KR)

(21) Appl. No.: 18/641,817

(22) Filed: Apr. 22, 2024

(30) Foreign Application Priority Data
May 24, 2023 (KR) 10-2023-0067044

(51) Int. Cl. H10K 59/80; H10K 102/00

(52) U.S. Cl. CPC H10K 59/80; H10K 2102/311

(57) ABSTRACT

Provided is a display device including a display panel including a first non-folding region, a folding region, and a second non-folding region which are sequentially arranged along a first direction, a first metal plate including a plurality of holes overlapping the folding region on a plane, and disposed below the display panel, a second metal plate disposed below the first metal plate, and an adhesive layer disposed between the first metal plate and the second metal plate, wherein at least one of the lower surface of the first metal plate or the upper surface of the second metal plate includes grooves overlapping the first non-folding region and the second non-folding region on a plane, wherein the adhesive layer is disposed in the grooves, so that the display device may ensure surface quality, and folding reliability.

This application claims priority to Korean Patent Application No. 10-2023-0067044, filed on May 24, 2023, and all the benefits accruing therefrom under 35 U.S.C. § 119, the entire contents of which are hereby incorporated by reference.

### BACKGROUND

### (1) Field

The present disclosure herein relates to a display device. More particularly, the present disclosure relates to a display device including a first metal plate and a second metal plate.

### (2) Description of the Related Art

An electronic device which provides images to a user, such as a smart phone, a digital camera, a laptop, a navigation system, and a smart television, includes a display device for displaying the images. The display device generates images, and provides the images to outside the display device, such as to a user, through a display screen of the display device.

With technology development of display devices, display devices of various shapes are being developed. For example, various display devices which may be deformed into a shape having a curved surface, folded, or rolled are being developed. The display devices which are deformable are easy to carry around, and may improve a user's convenience in using the display device.

A flexible display device may include a flexible display panel and a support plate which is disposed below the display panel. A plurality of holes for facilitating folding of the flexible display device may be defined in the support plate.

### SUMMARY

The present disclosure provides a display device whose surface quality, and folding reliability are improved.

An embodiment of the invention provides a display device including a display panel including a first non-folding region, a folding region, and a second non-folding region which are sequentially arranged along a first direction, a first metal plate including (or defining) holes overlapping the folding region on a plane, and disposed below the display panel, a second metal plate disposed below the first metal plate, and an adhesive layer disposed between the first metal plate and the second metal plate, where the first metal plate includes a lower surface adjacent to the second metal plate, and the second metal plate includes an upper surface adjacent to the first metal plate, where at least one of the lower surface of the first metal plate or the upper surface of the second metal plate includes grooves overlapping the first non-folding region and the second non-folding region on a plane, where the adhesive layer is disposed in the grooves.

In an embodiment, the second metal plate overlapping the folding region on a plane may be directly disposed below the first metal plate.

In an embodiment, the second metal plate may include a 2-1 metal plate overlapping the first non-folding region on a plane, and a 2-2 metal plate overlapping the second non-folding region on a plane, where the 2-1 metal plate and the 2-2 metal plate may be spaced apart by a first width in the first direction.

In an embodiment, the adhesive layer may not overlap the folding region on a plane, and the adhesive layer may include a first adhesive layer overlapping the first non-folding region on a plane, and a second adhesive layer overlapping the second non-folding region on a plane, where the first adhesive layer and the second adhesive layer may be spaced apart by a second width, which is larger than the first width, in the first direction.

In an embodiment, the adhesive layer may include a spacer particle and a thermosetting resin.

In an embodiment, the lower surface of the first metal plate may include the grooves, and a flat surface on which the grooves are not disposed.

In an embodiment, a portion of the second metal plate overlapping the grooves of the first metal plate on a plane may be disposed below the first metal plate with the adhesive layer interposed therebetween, and another portion of the second metal plate overlapping the flat surface of the first metal plate on a plane may be directly disposed below the first metal plate.

In an embodiment, the upper surface of the second metal plate may include the grooves, and a flat surface on which the grooves are not disposed.

In an embodiment, a portion of the first metal plate overlapping the grooves of the second metal plate on a plane may be disposed above the second metal plate with the adhesive layer interposed therebetween, and another portion of the first metal plate overlapping the flat surface of the second metal plate on a plane may be directly disposed above the second metal plate.

In an embodiment, the display device may further include a window disposed above the display panel.

In an embodiment of the invention, a display device includes a display panel including a first non-folding region, a folding region, and a second non-folding region which are sequentially arranged along a first direction, a first metal plate including a plurality of holes overlapping the folding region on a plane, and disposed below the display panel, a second metal plate disposed below the first metal plate, and an adhesive layer disposed between the first metal plate and the second metal plate, where the first metal plate includes an adhesive portion overlapping the first non-folding region and the second non-folding region on a plane, and a non-adhesive portion overlapping the folding region on a plane, and the non-adhesive portion of the first metal plate is directly disposed above the second metal plate, and the adhesive portion of the first metal plate is disposed above the second metal plate with the adhesive later interposed therebetween.

In an embodiment, the second metal plate may include a 2-1 metal plate overlapping the first non-folding region on a plane, and a 2-2 metal plate overlapping the second non-folding region on a plane, where the 2-1 metal plate and the 2-2 metal plate may be spaced apart by a first width in the first direction.

In an embodiment, the adhesive layer may not overlap the folding region on a plane, and the adhesive layer may include a first adhesive layer overlapping the first non-folding region on a plane, and a second adhesive layer overlapping the second non-folding region on a plane, where the first adhesive layer and the second adhesive layer may be spaced apart by a second width, which is larger than the first width, in the first direction.

In an embodiment, the adhesive layer may include a spacer particle and a thermosetting resin.

In an embodiment, the first metal plate may include a lower surface adjacent to the second metal plate, and on the lower surface corresponding to the adhesive portion of the first metal plate, a groove may be defined, where in the groove of the first metal plate, the adhesive layer may be disposed.

In an embodiment, on the lower surface corresponding to the non-adhesive portion of the first metal plate, a flat substrate may be defined.

In an embodiment, on the adhesive layer, a lower surface in contact with the second metal plate may be defined, where the flat surface of the first metal plate and the lower surface of the adhesive layer may be disposed on the same plane.

In an embodiment, the second metal plate may include an upper surface adjacent to the first metal plate, where on the upper surface of the second metal plate corresponding to the adhesive portion of the first metal plate on a plane, a groove may be defined, where in the groove of the second metal plate, the adhesive layer may be disposed.

In an embodiment, on the upper surface of the second metal plate corresponding to the non-adhesive portion of the first metal plate on a plane, a flat surface may be defined.

In an embodiment, on the adhesive layer, an upper surface in contact with the first metal plate may be defined, where the flat surface of the second metal plate and the upper surface of the adhesive layer may be disposed on the same plane.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of an electronic device in an unfolded state according to an embodiment of the invention;

FIG. 2 is a perspective view of an electronic device in a folded state according to an embodiment of the invention;

FIG. 3 is an exploded perspective view of an electronic device according to an embodiment of the invention;

FIG. 4 is a block diagram of an electronic device according to an embodiment of the invention;

FIG. 5 is a cross-sectional view of a display panel according to an embodiment of the invention;

FIG. 6 is a plan view of a display module according to an embodiment of the invention;

FIG. 7A is a cross-sectional view of a display device according to an embodiment of the invention;

FIG. 7B is a perspective view of a display module according to an embodiment of the invention;

FIG. 7C is a plan view of an enlarged portion of a display module according to an embodiment of the invention;

FIG. 8A is a cross-sectional view of a display device according to an embodiment of the invention;

FIG. 8B is a perspective view of a display module according to an embodiment of the invention;

FIG. 9 is a perspective view of an electronic device according to an embodiment of the invention; and

FIG. 10 is a perspective view of an electronic device according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements. Within the Figures and the text of the disclosure, a reference number indicating a singular form of an element may also be used to reference a plurality of the singular element. Also, in the drawings, the thickness, the ratio, and the dimensions of elements are exaggerated for an effective description of technical contents.

In the present disclosure, when an element (or a region, a layer, a portion, etc.) is referred to as being related to another element such as being “on,” “connected to,” or “coupled to” another element, it means that the element may be directly disposed on/connected to/coupled to the other element, or that a third element may be disposed therebetween. In contrast, when an element (or a region, a layer, a portion, etc.) is referred to as being related to another element such as being “directly on,” “directly connected to,” or “directly coupled to” another element, it means that a third element is not disposed therebetween.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” The term “and/or” includes any and all combinations of one or more of which associated elements may define.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the invention. The terms of a singular form may include plural forms unless the context clearly indicates otherwise.

In addition, terms such as “below,” “lower,” “above,” “upper,” and the like are used to describe the relationship of the elements shown in the drawings. The terms are used as a relative concept and are described with reference to the direction indicated in the drawings.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which the invention pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

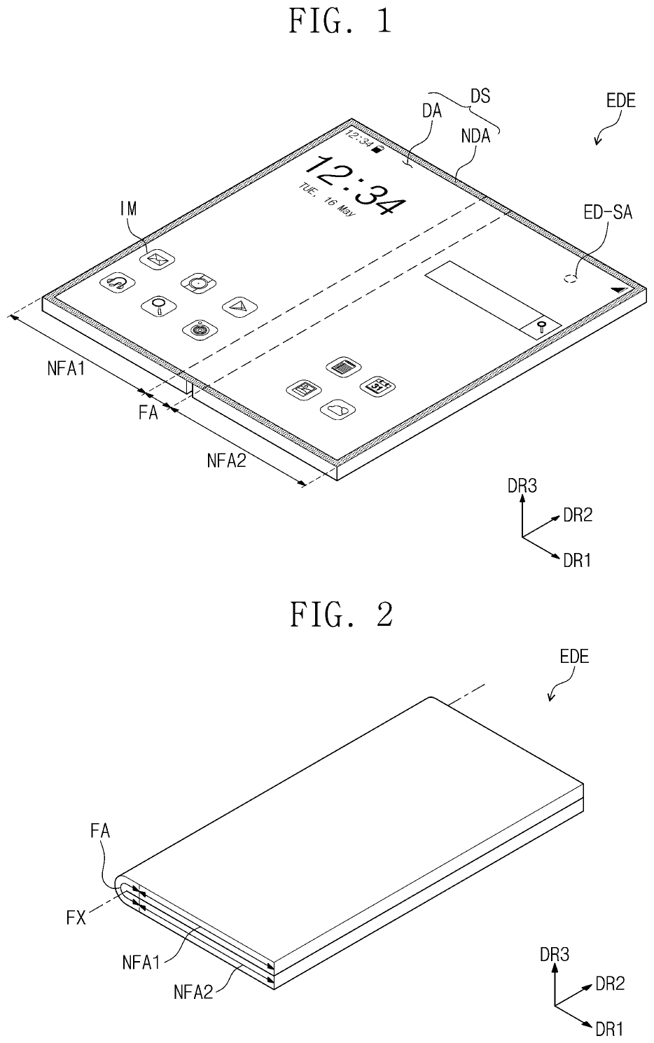

FIG. 1 is a perspective view of an electronic device EDE in an unfolded state according to an embodiment of the invention. FIG. 2 is a perspective view of the electronic device EDE in a folded state according to an embodiment of the invention.

Referring to FIG. 1 and FIG. 2, the electronic device EDE according to an embodiment of the invention may include a display surface DS in a plane defined by a first direction DR1 and a second direction DR2 which intersects the first direction DR1. The electronic device EDE may provide an image IM to outside the electronic display device (e.g., the electronic device EDE), such as to a user, through the display surface DS.

The display surface DS may include a display region DA and a non-display region NDA which is adjacent to the display region DA. The non-display region NDA may be extended around the display region DA, in a plan view. The display region DA may display the image IM, and the non-display region NDA may not display the image IM. The non-display region NDA may surround the display region DA, in the plan view. However, the embodiment of the invention is not limited thereto, and the shape of the display region DA and the shape of the non-display region NDA may change.

Hereinafter, a direction intersecting a plane defined by the first direction DR1 and the second direction DR2 crossing each other, is defined as a third direction DR3. The first, second and third directions DR1, DR2 and DR3 may be respectively and substantially perpendicular to each other, without being limited thereto. In addition, in the present disclosure, “on a plane” may be defined as a state viewed in the third direction DR3. The electronic display device and various components or layers thereof may have a thickness defined along the third direction DR3, to define a thickness direction.

In the display region DA of the electronic device EDE, a sensor region ED-SA as a sensing region may be defined. FIG. 1 exemplarily illustrates one sensor region ED-SA, but the number of the sensor region ED-SA is not limited thereto. The sensor region ED-SA may be a portion of the display region DA. That is, a planar area of the sensor region ED-SA may be a portion of the overall planar area of the display region DA. Therefore, the electronic device EDE may display an image IM through the sensor region ED-SA. However, the embodiment of the invention is not limited thereto. For example, a portion of components, layers, etc. of a display panel DP which corresponds to the sensor region ED-SA may be removed or omitted, so that the sensor region ED-SA may not display an image IM.

In a region overlapping the sensor region ED-SA, an electronic module which provides a function to the electronic display device may be disposed. The electronic module may receive an external input from outside the electronic display device and transmitted through the sensor region ED-SA, or may provide an output to outside the electronic display device, through the sensor region ED-SA. For example, the electronic module may be a camera module CMM functioning to capture an external image, a sensor for measuring a distance, such as a proximity sensor functioning to sense an external object and a distance from the electronic display device, a sensor for recognizing a body part (e.g., a user's body part like a fingerprint, an iris or a face) to function as a biometric function, or a small lamp for outputting light, but is not particularly limited thereto. Hereinafter, an example in which an electronic module overlapping the sensor region ED-SA is a camera module CMM will be described.

The electronic device EDE may include a folding region FA, and a non-folding region provided in plural including a plurality of non-folding regions NFA1 and NFA2. The non-folding regions NFA1 and NFA2 may include a first non-folding region NFA1 and a second non-folding region NFA2. The folding region FA may be disposed between the first non-folding region NFA1 and the second non-folding region NFA2. The folding region FA may be referred to as a foldable region at which the electronic display device and various components or layers thereof are foldable, and the first and second non-folding regions NFA1 and NFA2 may be referred to as first and second non-foldable regions at which the electronic display device and various components or layers thereof are non-foldable or remain substantially flat even in the electronic display device is folded at the folding region FA. One or more component or layer of the electronic display device may be foldable, bendable, rollable, etc. together with each other.

As illustrated in FIG. 2, the folding region FA may be foldable with respect to a folding axis FX parallel to the second direction DR2. In a state in which the electronic device EDE is folded, the folding region FA may have a predetermined curvature and a predetermined radius of curvature. The first non-folding region NFA1 and the second non-folding region NFA2 may face each other in the electronic display device which is folded. Here, the electronic device EDE may be inner-folded (or in-folded) such that portions of the display surface DS face each other and are not exposed to the outside.

In an embodiment of the invention, the electronic device EDE may be outer-folded (or out-folded) such that portions of the display surface DS face in a direction away from each other to be exposed to the outside (e.g., the outside of the electronic display device). In an embodiment of the invention, the electronic device EDE may be inner-folded or outer-folded from an initial state of being unfolded or flat, but is not limited thereto. In an embodiment of the invention, the electronic device EDE may be configured to operate in one or more among an un-folding operation, an inner-folding operation, and an outer-folding operation. In an embodiment of the invention, a plurality of folding axes are defined in the electronic device EDE, and the electronic device EDE may be inner-folded or outer-folded from an unfolding operation with respect to each of the plurality of folding axes.

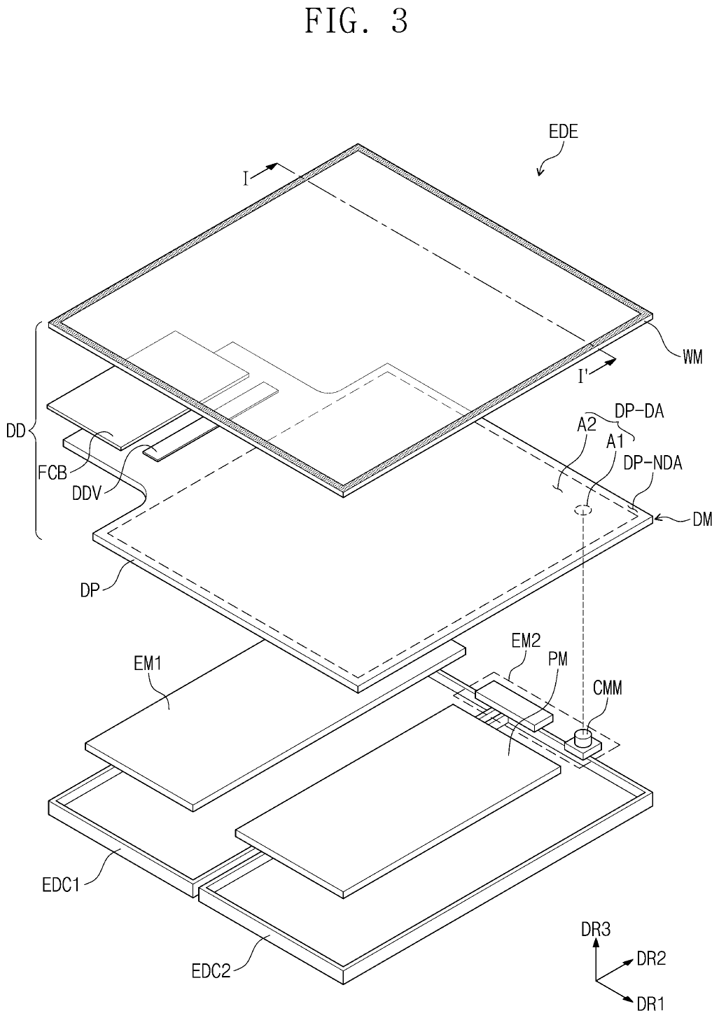

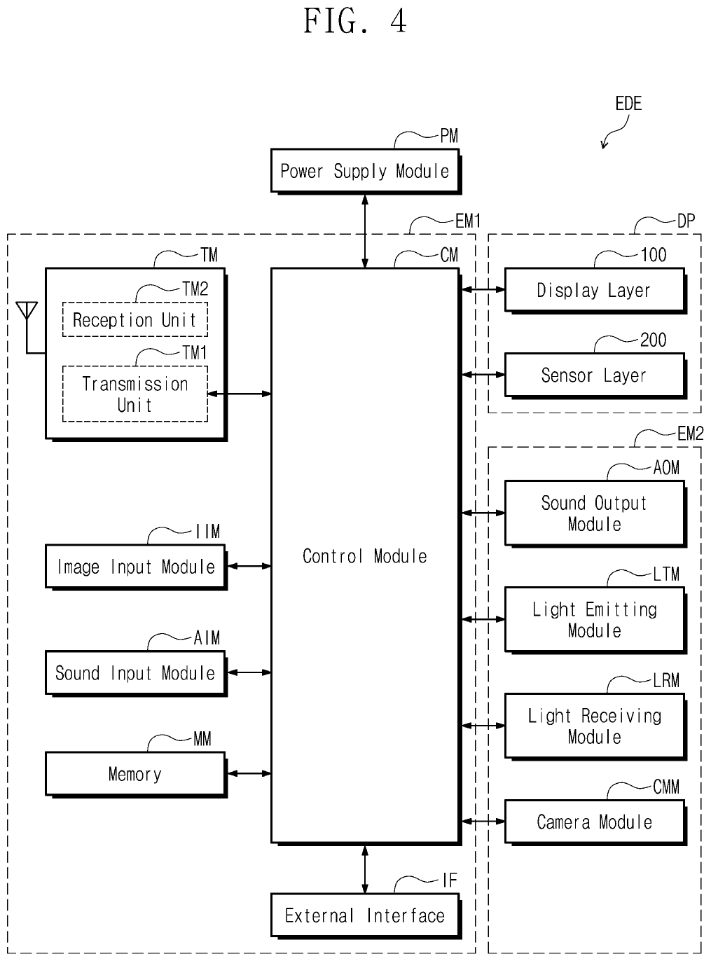

FIG. 3 is an exploded perspective view of the electronic device EDE according to an embodiment of the invention. FIG. 4 is a block diagram of the electronic device EDE according to an embodiment of the invention.

Referring to FIG. 3 and FIG. 4, the electronic device EDE may include a display device DD, a first electronic module EM1, a second electronic module EM2, a power supply module PM, and housings EDC1 and EDC2. The electronic device EDE may further include an instrument structure or folding controller for controlling a folding operation of the display device DD.

The display device DD may include a window module WM and a display module DM. The window module WM may provide the front surface of the electronic device EDE. The display module DM may include at least a display panel DP. The display module DM may generate an image and/or may sense an external input.

FIG. 3 illustrates that the display module DM is essentially the same element as the display panel DP, but substantially, the display module DM may be a stacking structure in which a plurality of components including the display panel DP are stacked to form the display module DM. The stacking structure of the display module DM will be described in detail later.

The display panel DP may include a display region DP-DA (e.g., a display area having a planar area) and a non-display region DP-NDA (e.g., a non-display area having a planar area) respectively corresponding to the display region DA (see FIG. 1) and the non-display region NDA (see FIG. 1) of the electronic device EDE. In the present disclosure, when “a region/portion corresponds to a region/portion,” it means that the region/portion overlaps the region/portion, and the regions/portions are not limited to having the same area (e.g., planar area). As “corresponding,” for example, a portion of one element may be aligned along a thickness direction with a portion of another element, without being limited thereto.

The display region DP-DA may include a first region A1 and a second region A2. The first region A1 may overlap or correspond to the sensor region ED-SA (see FIG. 1) of the electronic device EDE. In the present embodiment, the first region A1 is illustrated in a circular shape, but may have various planar shapes such as a polygon, an ellipse, a figure with at least one curved side, or an irregular shape, and is not limited to any one embodiment. The first region A1 may be referred to as a component region, and the second region A2 may be referred to as a main display region or a general display region. A planar area of the first region A1 may form a portion of the overall planar area of the second region A2.

The first region A1 may have a higher transmittance (e.g., higher light transmittance) than the second region A2. Alternatively, the resolution of the first region A1 may be lower than the resolution of the second region A2, but is not limited thereto. For example, the first region A1 has a higher transmittance than the second region A2, but the resolution of the first region A1 may be substantially the same as the resolution of the second region A2. The first region A1 may overlap a camera module CMM to be described later. In an embodiment of the invention, a portion of one or more components, layers, etc. which is within the display panel DP and overlapping the first region A1 may be removed. Therefore, an image IM may not be displayed in the first region A1, but is not limited thereto.

The display panel DP may include a display layer 100 (e.g., an image display layer) and a sensor layer 200.

The display layer 100 may be a component or collection thereof which substantially generates an image IM. The display layer 100 may be a light emitting type display layer. Here, for example, the display layer 100 may be an organic light emitting display layer (e.g., organic LED layer), an inorganic light emitting display layer, an organic-inorganic light emitting display layer, a quantum-dot display layer, a micro-LED display layer, or a nano-LED display layer.

The sensor layer 200 may be disposed on the display layer 100. The sensor layer 200 may sense an external input applied from the outside. The external input may be a user input from a user. The user input may include various forms of external inputs such as light, heat, pressure, proximity, etc. The external input may be applied from an input tool such as a part of a user's body, a pen, an external object, and the like.

The display module DM may further include an anti-reflection layer (not shown) disposed on the sensor layer 200. During the manufacturing of (or providing of) the display module DM, the anti-reflection layer may be directly formed on the sensor layer 200. The anti-reflection layer may be defined as an external light anti-reflection film. The anti-reflection layer may reduce the reflectance of external light incident from above the display device DD (e.g., part of the outside) toward the display panel DP.

Illustratively, the sensor layer 200 may be directly formed on the display layer 100, and the anti-reflection layer may be directly formed on the sensor layer 200, but the embodiment of the invention is not limited thereto. For example, the sensor layer 200 may be separately manufactured or provided and subsequently attached to the display layer 100 by a separate element such as an adhesive layer, and the anti-reflection layer may be separately manufactured or provided and subsequently attached to the sensor layer 200 by an adhesive layer.

The display module DM may include a data driver DDV disposed on the non-display region NDA, such as being connected to the display panel DP at the non-display area thereof. The display module DM may further include a flexible circuit film FCB coupled to the non-display region DP-NDA, such as being coupled to the display panel DP at the non-display area thereof.

The data driver DDV may include driving elements for driving a pixel PX of the display panel DP, for example, a data driving circuit. FIG. 3 illustrates a structure in which the data driver DDV is mounted on the display panel DP, but the invention is not limited thereto. For example, the data driver DDV may be mounted on the flexible circuit film FCB.

The power supply module PM may supply power required for the overall operation of the electronic device EDE. The power supply module PM may include a typical battery module.

The first electronic module EM1 and the second electronic module EM2 may include various functional modules for operating the electron device EDE. Each of the first electronic module EM1 and the second electronic module EM2 may be directly mounted on a mother board electrically connected to the display panel DP, or may be mounted on a separate substrate and electrically connected to the mother board through a connector (not shown) and the like.

The first electronic module EM1 may include a control module CM, a wireless communication module TM, an image input module IIM, a sound input module AIM, a memory MM, and an external interface IF.

The control module CM may control the overall operation of the electronic apparatus EDE (e.g., a controller). The control module CM may be a microprocessor. For example, the control module CM either activates or deactivates the display panel DP. The control module CM may control other modules, such as the image input module IIM or the audio input module AIM, on the basis of an external input such as a touch signal received from the display panel DP.

The wireless communication module TM may communicate with an external electronic device via a first network (e.g., a short-range communication network such as Bluetooth, WiFi direct, or an infrared data association (IrDA)) or a second network (e.g., a long-range communication network such as a cellular network, the Internet, or a computer network (e.g., a LAN or WAN)). Communication modules included in the wireless communication module TM may be integrated into one component (e.g., a single chip), or may be implemented as a plurality of components (e.g., a plurality of chips) separated from each other. The wireless communication module TM may transmit/receive voice signals using a general communication line. The wireless communication module TM may include a transmission unit TM1 for modulating and then transmitting a signal to be transmitted, and a reception unit TM2 for demodulating a received signal.

The image input module IIM may process an image signal and convert the processed image signal into image data displayable on the display panel DP. The sound input module AIM may receive an external sound signal through a microphone in a recording mode, a voice recognition mode, and the like and convert the received external sound signal into electrical voice data.

The external interface IF may include a connector capable of physically connecting the electronic device EDE and the external electronic device to each other. For example, the external interface IF may serve as an interface which is connected to an external charger, a wired/wireless data port, a card (e.g., a memory card, a SIM/UIM card) socket, and the like.

The second electronic module EM2 may include a sound output module AOM, a light emitting module LTM, a light receiving module LRM, and a camera module CMM. The sound output module AOM may convert sound data received from the wireless communication module TM or sound data stored in the memory MM, and output the converted sound data to the outside.

The light emitting module LTM may generate and output a light. The light emitting module LTM may output infrared rays. The light emitting module LTM may include an LED element. The light receiving module LRM may sense infrared rays. The light receiving module LRM may be activated when infrared rays of a predetermined level or higher are sensed. The light receiving module LRM may include a CMOS sensor. After infrared light generated in the light emitting module LTM is output, the infrared light is reflected by an external object (e.g., a body part, an external object, etc.), and the reflected infrared light may be incident on the light receiving module LRM.

The camera module CMM may capture still images and moving images. The camera module CMM may be provided in plurality. Some of the camera modules CMM may overlap the first region A1. The external input (e.g., light) may be provided to the camera module CMM through the first region A1. For example, the camera module CMM may capture an external image by receiving natural light from outside the electronic display device, through the first region A1.

The housings EDC1 and EDC2 may provide a receiving space in which the display module DM, the first and second electronic modules EM1 and EM2, and the power supply module PM are accommodated. The housings EDC1 and EDC2 may protect components accommodated in the housings EDC1 and EDC2, such as the display module DM, the first and second electronic modules EM1 and EM2, the power supply module PM, and the like, from an outside environment, from impacts, etc. FIG. 3 exemplarily illustrates two housings EDC1 and EDC2 separated (or disconnected) from each other, but the embodiment of the invention is not limited thereto. Although not shown, the electronic device EDE may further include a hinge structure for connecting the two housings EDC1 and EDC2. The housings EDC1 and EDC2 may be coupled to the window module WM.

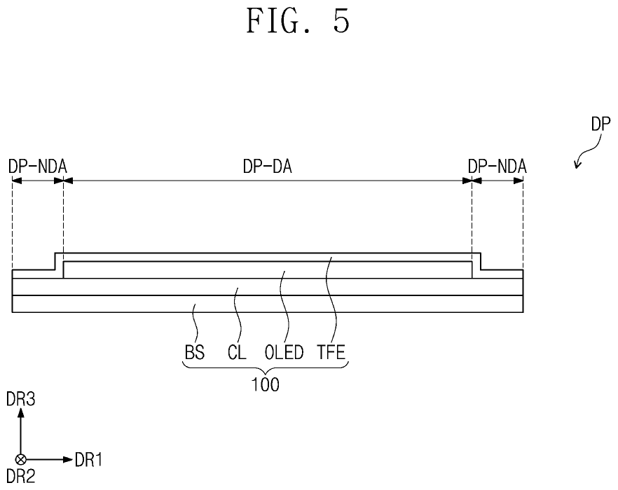

FIG. 5 is a cross-sectional view of the display panel DP according to an embodiment of the invention.

FIG. 5 exemplarily illustrates the display panel DP of FIG. 3 and FIG. 4, and omits the sensor layer 200 and illustrates the display layer 100.

Referring to FIG. 5, the display panel DP may include the display region DP-DA and the non-display region DP-NDA which is around the display region DP-DA. The display panel DP may include a base layer BS, a circuit layer CL, a light emitting element layer OLED, and an encapsulation layer TFE.

The base layer BS may provide a base surface on which the circuit layer CL is disposed. The base layer BS may be a flexible substrate capable of bending, folding, rolling, or the like. The base layer BS may include a plastic substrate, a glass substrate, a metal substrate, an organic/inorganic composite material substrate, or the like. The base layer BS may have a multi-layered structure. For example, the base layer BS may include an inorganic layer, a synthetic resin layer, or a composite material layer.

The circuit layer CL may be disposed on the base layer BS. The circuit layer CL may include at least one insulation layer, a semiconductor pattern, and a conductive pattern. Through coating, deposition, or the like, an insulation layer, a semiconductor layer, and a conductive layer are formed (or provided), and then the insulation layer, the semiconductor layer, and the conductive layer are patterned through a plurality of times of photolithography to form the insulation layer, the semiconductor pattern, and the conductive pattern of the circuit layer CL. The insulation layer, the semiconductor pattern, and the conductive pattern included in the circuit layer CL may form driving elements such as a transistor, signal lines, and pads PD in the circuit layer CL.

The light emitting element layer OLED may be disposed on the circuit layer CL. The light emitting element layer OLED may include light emitting elements. The light emitting elements of the light emitting element layer OLED may be electrically connected to the driving elements of the circuit layer CL, and may generate light according to a signal provided by the driving elements.

The encapsulation layer TFE may be disposed on the light emitting element layer OLED, and may encapsulate the light emitting elements. The encapsulation layer TFE may include at least one thin film for improving optical efficiency of the light emitting element layer OLED, or for protecting the light emitting element layer OLED. The encapsulation layer TFE may protect the light emitting element layer OLED from moisture, oxygen, and external foreign substances.

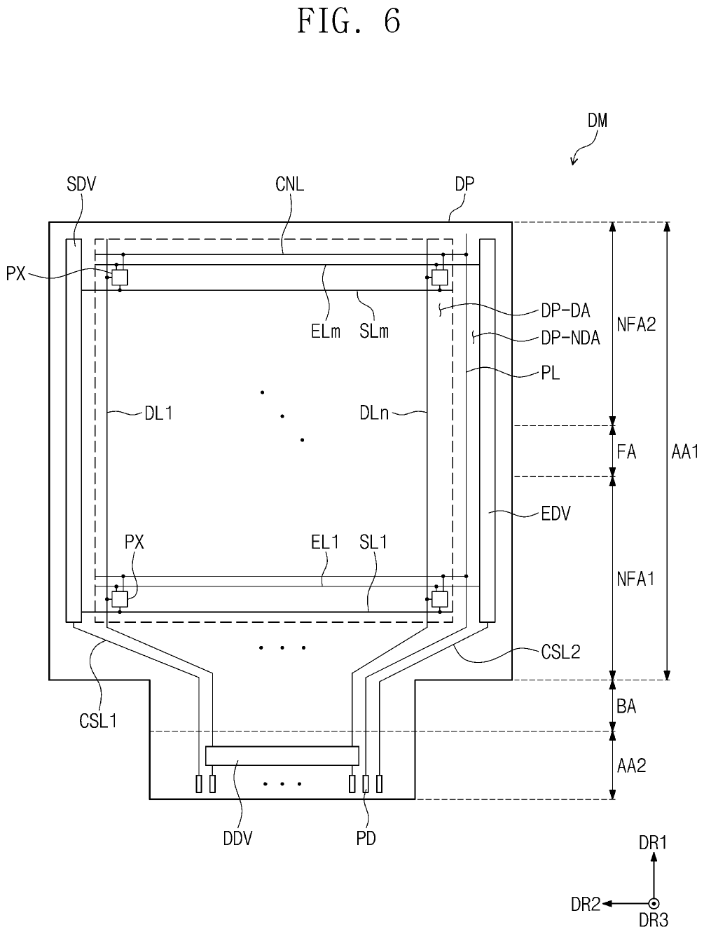

FIG. 6 is a plan view of the display module DM according to an embodiment of the invention.

Referring to FIG. 6, the display module DM may include a display panel DP, a scan driver SDV, a data driver DDV, and an emission driver EDV.

The display panel DP may include a first region AA1, a second region AA2, and a bending region BA between the first region AA1 and the second region AA2. The bending region BA may have a major dimension extended in the second direction DR2, and the first region AA1, the bending region BA, and the second region AA2 may be arranged in order along the first direction DR1.

The first region AA1 may include a display region DP-DA and a non-display region DP-NDA which is around the display region DP-DA. The non-display region DP-NDA may surround the display region DP-DA. The display region DP-DA may be a region (or planar area) which displays an image IM, and the non-display region DP-NDA may be a region which does not display an image IM. The second region AA2 and the bending region BA may be regions which do not display an image IM, such as to form a part of the non-display area of the display panel DP.

The first region AA1 may include, when viewed in the second direction DR2, a first non-folding region NFA1, a second non-folding region NFA2, and a folding region FA between the first non-folding region NFA1 and the second non-folding region NFA2.

The display panel DP may include a pixel PX provided in plural including a plurality of pixels PX, a scan line provided in plural including a plurality of scan lines SL1 to SLm, a data line provided in plural including a plurality of data lines DL1 to DLn, an emission line provided in plural including a plurality of emission lines ELI to ELm, first and second control lines CSL1 and CSL2, a power line PL, a connection line CNL provided in plural including a plurality of connection lines CNL, and a pad PD provided in plural including a plurality of pads PD. Here, ‘m’ and ‘n’ are natural numbers. The pixels PX are disposed in the display region DP-DA, and may be respectively connected to corresponding signal lines among the scan lines SL1 to SLm, the data lines DL1 to DLn, and the emission lines ELI to ELm.

The scan driver SDV and the emission driver EDV may be disposed in the non-display region DP-NDA. The scan driver SDV and the emission driver EDV may be disposed in a portion of the non-display region DP-NDA which is respectively adjacent to opposing sides of the first region AA1, which are opposite to each other along the second direction DR2. The data driver DDV may be disposed in the second region AA2. The data driver DDV may be manufactured in the form of an integrated circuit chip and mounted on the display panel at the second region AA2.

The scan lines SL1 to SLm may be extended in the second direction DR2 and connected to the scan driver SDV. The data lines DL1 to DLn are extended in the first direction DR1, and may be connected to the data driver DDV via signal lines or conductive lines in the bending region BA. The emission lines ELI to ELm may be extended in the second direction DR2 and connected to the emission driver EDV.

The power line PL may be extended in the first direction DR1 and disposed in the non-display region DP-NDA. The power line PL may be disposed between the display region DP-DA and the emission driver EDV, but is not limited thereto. In an embodiment, the power line PL may be disposed between the display region DP-DA and the scan driver SDV.

The power line PL may be extended to the second region AA2, via the bending region BA. When viewed on a plane, the power line PL may be extended from the first region A1, toward a lower end of the second region AA2. The power line PL may receive a driving voltage.

The connection lines CNL may be extended along the second direction DR2 and arranged along the first direction DR1. The connection lines CNL may be connected to the power line PL and the pixels PX. The driving voltage may be applied to the pixels PX through the power line PL and the connection lines CNL connected to each other.

A first control line CSL1 is connected to the scan driver SDV, and may be extended toward the lower end of the second region AA2, via the bending region BA. A second control line CSL2 is connected to the emission driver EDV, and may be extended toward the lower end of the second region AA2, via the bending region BA. The data driver DDV may be disposed between the first control line CSL1 and the second control line CSL2.

When viewed on a plane, the pads PD may be disposed adjacent to the lower end of the second region AA2. The data driver DDV, the power line PL, the first control line CSL1, and the second control line CSL2 may be variously connected to the pads PD.

The data lines DL1 to DLn may be connected to corresponding pads PD through the data driver DDV. For example, the data lines DL1 to DLn are connected to the data driver DDV, and the data driver DDV may be connected to the pads PD respectively corresponding to the data lines DL1 to DLn.

Although not illustrated, a printed circuit board as an external component is connected to the display panel DP via the pads PD, and a timing controller and a voltage generator may be disposed on the printed circuit board. The timing controller may be manufactured as an integrated circuit chip and mounted on the printed circuit board. The timing controller and the voltage generator may be connected to the display panel DP at the pads PD thereof, through the printed circuit board.

The timing controller may control the operation of the scan driver SDV, the data driver DDV, and the emission driver EDV. The timing controller may generate electronic signals such as a scan control signal, a data control signal, and an emission control signal in response to other electronic signals such as control signals received from the outside. The voltage generator may generate a driving voltage.

The scan control signal may be provided to the scan driver SDV through the first control line CSL1. The emission control signal may be provided to the emission driver EDV through the second control line CSL2. The data control signal may be provided to the data driver DDV. The timing controller receives image signals from the outside, and may convert the data format of the image signals to match interface specifications with the data driver DDV and provide the image signals with converted data format to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to the image signals in response to the data control signal. The data voltages may be applied to the pixels PX through the data lines DL1 to DLn. The emission driver EDV may generate a plurality of emission signals in response to the emission control signal. The emission signals may be applied to the pixels PX through the emission lines ELI to ELm.

The pixels PX may be provided with the data voltages in response to the scan signals. The pixels PX may display an image by emitting light of luminance corresponding to the data voltages in response to the emission signals. The emission duration of the pixels PX may be controlled by the emission signals.

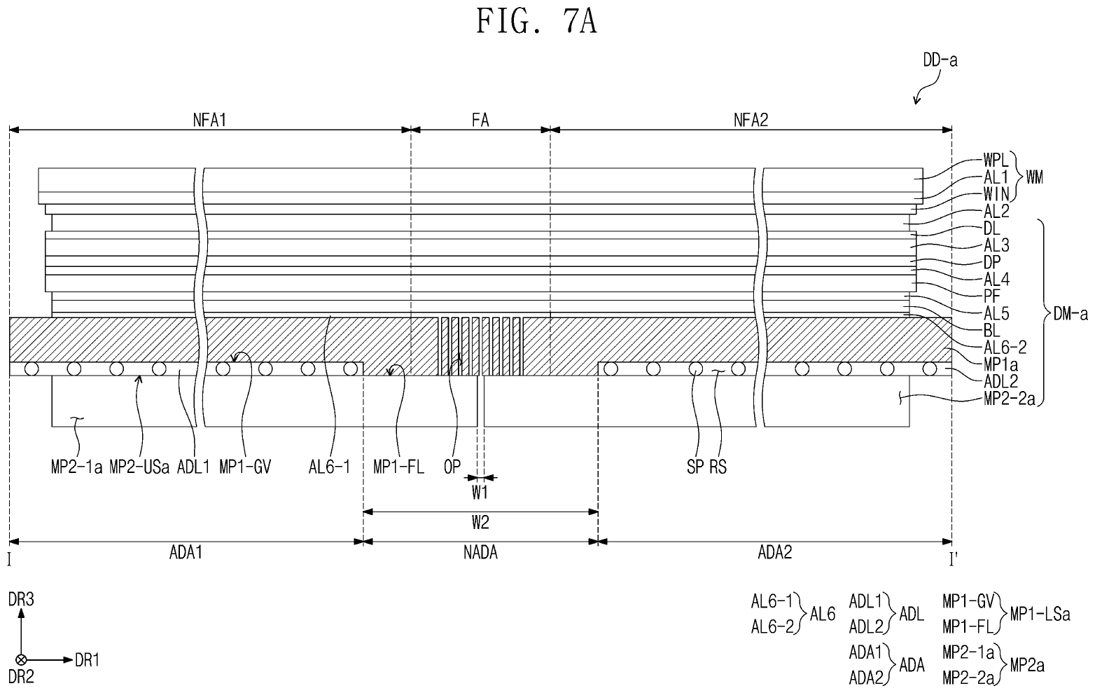

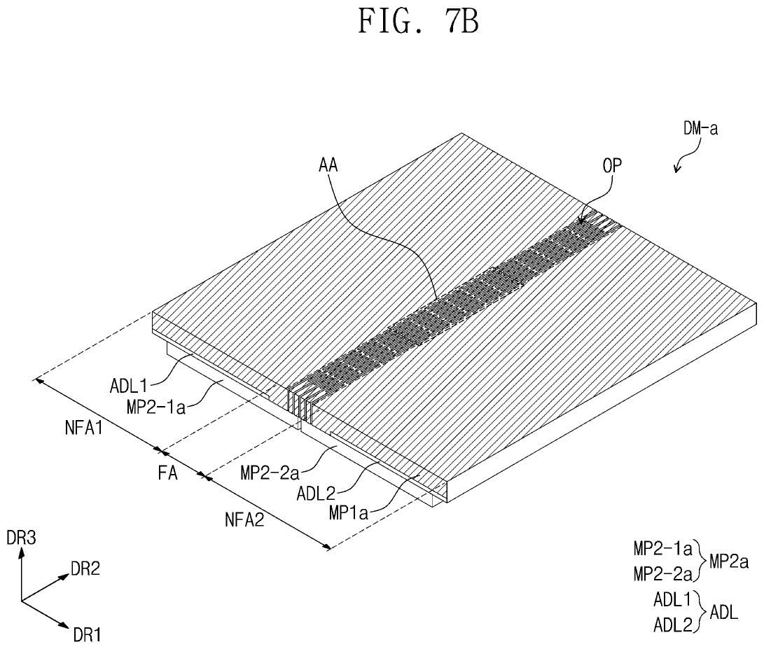

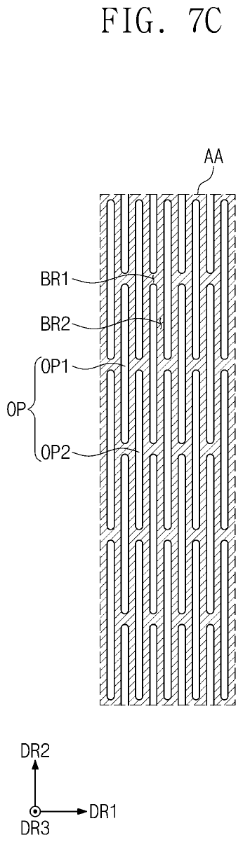

FIG. 7A is a cross-sectional view of a display device DD-a according to an embodiment of the invention. FIG. 7B is a perspective view of some components of a display module DM-a according to an embodiment of the invention. FIG. 7C is a plan view of an enlarged plan view of the display module DM-a according to an embodiment of the invention.

FIG. 7A is an embodiment of a cross-section corresponding line I-I′ of the display device DD of FIG. 3. FIG. 7B is a perspective view exemplarily illustrating some components of the display module DM-a of FIG. 7A. FIG. 7C is a plan view exemplarily illustrating a portion AA of FIG. 7B.

Referring to FIG. 7A, the display device DD-a may include a window module WM, and the display module DM-a facing each other. The display device DD-a may include an adhesive layer AL2 disposed between the window module WM and the display module DM-a to couple these elements to each other. The display device DD-a may include adhesive layers AL1, AL3, AL4, AL5, and AL6 variously disposed between a plurality of layers included in the window module WM or the display module DM-a. In an embodiment, one or more of the adhesive layers AL1, AL3, AL4, AL5, and AL6 may be omitted.

The adhesive layers AL1, AL2, AL3, AL4, AL5, and AL6 may include any one among optical clear adhesives (OCA), optical clear resins (OCR), and pressure sensitive adhesives (PSA).

The window module WM may be disposed on the display module DM-a such as to face each other along the thickness direction. The window module WM may transmit an image IM provided from the display module DM-a, and at the same time, may mitigate an external impact to other layers within the display device DD-a. Accordingly, the window module WM may prevent the display module DM-a from being damaged or malfunctioning due to the external impact.

The window module WM may include a window WIN, a window protection layer WPL disposed on the window module WM, and the adhesive layer AL1 disposed between the window WIN and the window protection layer WPL. In an embodiment, one or more among the window protection layer WPL and the adhesive layer AL1 may be omitted.

The window WIN may be disposed on the display module DM-a. The window WIN may protect the display module DM-a from an external scratch. The window WIN may have optically transparent properties. The window WIN may include glass. However, the embodiment of the invention is not limited thereto, and the window WIN may include a synthetic resin film. The window WIN may have a multi-layered structure or a single-layered structure. For example, the window WIN may include a plurality of synthetic resin films bonded with an adhesive, or a glass substrate and a synthetic resin film bonded with an adhesive.

The window protection layer WPL may be disposed on the window WIN. The window protection layer WPL may include a flexible plastic material such as polyimide or polyethylene terephthalate. A hard coating layer (not shown) may be disposed on the window protection layer WPL. The window protection layer WPL may provide an outer surface (e.g., front surface) of the display device DD-a. The window protection layer WPL may include a thickness portion as the hard coating layer which provides the outer surface of the display device DD-a at the window protection layer WPL.

The display module DM-a may include the display panel DP. The display module DM-a may include an impact absorption layer DL disposed above the display panel DP. The display module DM-a may include a panel protection layer PF, a barrier layer BL, a first metal plate MP1a, and a second metal plate MP2a, which are disposed below the display panel DP. The display module DM-a may include an adhesive layer ADL disposed between the first metal plate MP1a and the second metal plate MP2a.

The same contents as those described above with reference to FIG. 1 to FIG. 6 may be applied to the display panel DP.

The impact absorption layer DL may be disposed on the display panel DP. The impact absorption layer DL may protect the display panel DP by adsorbing an external impact applied from above the display device DD-a and toward the display panel DP. The impact absorption layer DL may be in the form of a stretch film. The impact absorption layer DL may include a flexible plastic material. The flexible plastic material may be defined as a synthetic resin film. For example, the impact absorption layer DL may include a flexible plastic material such as polyimide (PI) or polyethylene terephthalate (PET). The impact absorption layer DL may be coupled to the display panel DP by a third adhesive layer AL3.

The panel protection layer PF may be disposed below the display panel DP. The panel protection layer PF may be disposed below the display panel DP, and may protect a lower portion of the display panel DP. The panel protection layer PF may include a flexible plastic material. For example, the panel protection layer PF may include polyethylene terephthalate (PET). The panel protection layer PF may be coupled to the display panel DP by a fourth adhesive layer AL4.

The barrier layer BL may be disposed below the panel protection layer PF. The barrier layer BL may increase resistance against compressive force caused by external pressing. Therefore, the barrier layer BL may serve to prevent the deformation of the display panel DP. The barrier layer BL may include a flexible plastic material such as polyimide or polyethylene terephthalate. The barrier layer BL may have a color which absorbs light. For example, the barrier layer BL may a black color. In this case, when the display module DM-a is viewed from above the display module DM-a, components disposed below the barrier layer BL may not be visually recognized. The barrier layer BL may be coupled to the panel protection layer PF by a fifth adhesive layer AL5.

The first metal plate MP1a may be disposed below the display panel DP. For example, the first metal plate MP1a may be disposed below the barrier layer BL. The first metal plate MP1a may be coupled to the barrier layer BL by a sixth adhesive layer AL6. The sixth adhesive layer AL6 may include a 6-1 adhesive layer AL6-1 (e.g., first adhesive pattern) and a 6-2 adhesive layer AL6-2 (e.g., a second adhesive pattern) spaced apart from the 6-1 adhesive layer AL6-1 in the first direction DR1. The 6-1 adhesive layer AL6-1 may couple a portion of a barrier layer BL overlapping the first non-folding region NFA1 and a portion of the first metal plate MP1a to each other, and the 6-2 adhesive layer AL6-2 may couple a portion of the barrier layer BL overlapping the second non-folding region NFA2 and a portion of the first metal plate MP1a to each other.

The first metal plate MP1a may be disposed below the display panel DP and support the display panel DP. The first metal plate MP1a may be defined as a first support plate.

The first metal plate MP1a includes a metal material. The first metal plate MP1a may include a metal material having a high modulus (e.g., a high clastic modulus). For example, the first metal plate MP1a may include stainless steel. Therefore, the supporting force of the first metal plate MP1a supporting the display panel DP may be improved. The first support plate may include a hole OP provided in plural including holes OP, defined therein. In addition, the deformation of a portion of the first support plate in which holes OP of the first metal plate MP1a corresponding to the folding region FA are defined, may also be prevented.

The first metal plate MP1a may include a lower surface MP1-LSa adjacent to (e.g., facing or closest to) the second metal plate MP2a to be described later. Along the lower surface MP1-LSa of the first metal plate MP1a, grooves MP1-GV and a flat surface MP1-FL may be defined. The grooves MP1-GV may be recessed from a plane of the flat surface MP1-FL. Specifically, for defining the lower surface MP1-LSa of the first metal plate MP1a, the grooves MP1-GV overlapping the first non-folding region NFA1 and the second non-folding region NFA2 may be defined. Lower surfaces of solid portions of the first support plate between which are defined the holes OP, may form a part of an overall lower surface of the first support plate, together with lower surfaces at both the grooves MP1-GV and the flat surface MP1-FL.

The grooves MP1-GV may be formed by an etching process. In addition, at the lower surface MP1-LSa of the first metal plate MP1a, the flat surface MP1-FL overlapping the folding region FA may be defined. The flat surface MP1-FL may be closer to the folding region FA than the grooves MP1-GV. The grooves MP1-GV may be open in a direction towards the second metal plate MP2a,

In the groove MP1-GV defined at the lower surface MP1-LSa of the first metal plate MP1a, the adhesive layer ADL to be described later may be disposed. The adhesive layer ADL may include a first adhesive layer ADL1 (e.g., a first adhesive portion) and a second adhesive layer ADL2 (e.g., a second adhesive portion). The first adhesive layer ADL1 may be disposed in a groove MP1-GV (e.g., a first groove) of the first metal plate MP1a which overlaps the first non-folding region NFA1, and the second adhesive layer ADL2 may be disposed in a groove MP1-GV (e.g., a second groove) of the first metal plate MP1a which overlaps the second non-folding region NFA2. Since the first metal plate MP1a includes the grooves MP1-GV and the adhesive layer ADL is disposed in the grooves MP1-GV, respectively, there may be no separation or step between the first metal plate MP1a corresponding to the folding region FA and the second metal plate MP2a. In an embodiment, an adhesive lower surface of the adhesive layer ADL may be coplanar with the flat surface MP1-FL, without being limited thereto, to effectively fill the step between the lower plate surface at the groove MP1-GV and the lower plate surface at the flat surface MP1-FL.

The second metal plate MP2a may be disposed below the first metal plate MP1a. The second metal plate MP2a includes a metal material. The second metal plate MP2a may include a metal material having a high modulus. For example, the second metal plate MP2a may include stainless steel. Therefore, the supporting force of the second metal plate MP2a which supports the first metal plate MP1a may be improved.

The second metal plate MP2a may include a 2-1 metal plate MP2-1a and a 2-2 metal plate MP2-2a. The 2-1 metal plate MP2-1a may overlap the first non-folding region NFA1, and the 2-2 metal plate MP2-2a may overlap the second non-folding region NFA2. The 2-1 metal plate MP2-1a and the 2-2 metal plate MP2-2a may be disposed spaced apart by a first gap having a first width W1 in the first direction DR1. The second metal plate MP2a may be disconnected at the first gap for an entire length of the second metal plate MP2a which is defined along the second direction DR2.

A portion of the second metal plate MP2a corresponding to the groove MP1-GV of the first metal plate MP1a on a plane (e.g., in a plan view) may be disposed below the first metal plate MP1a with the adhesive layer ADL interposed therebetween. The first metal plate MP1a and the adhesive layer ADL may be coplanar with each other. The 2-1 metal plate MP2-1a and the 2-2 metal plate MP2-2a may be coplanar with each other.

The portion of the second metal plate MP2a corresponding to the groove MP1-GV of the first metal plate MP1a may be coupled to the first metal plate MP1a through the adhesive layer ADL. Specifically, the 2-1 metal plate MP2-1a may be coupled to the first metal plate MP1a through the first adhesive layer ADL1 disposed in the first non-folding region NFA1, and the 2-2 metal plate MP2-2a may be coupled to the first metal plate MP1a through the second adhesive layer ADL2 disposed in the second non-folding region NFA2.

The portion of the second metal plate MP2a which overlaps the folding region FA on a plane may be directly disposed below the portion of the first metal plate MP1a which overlaps the folding region FA. Specifically, another portion of the second metal plate MP2a which corresponds to the flat surface MP1-FL of the first metal plate MP1a on a plane may be directly disposed below the first metal plate MP1a at the flat surface MP1-FL thereof. Since the another portion of the second metal plate MP2a is directly disposed below the flat surface MP1-FL of the first metal plate MP1a, the flat surface MP1-FL of the first metal plate MP1a may be directly supported without deformation such as sagging.

In addition, since the deformation of the first metal plate MP1a of the folding region FA is prevented, deformation of the display panel DP disposed above the first metal plate MP1a or a folding region FA of the window WIN may also be prevented. That is, the folding reliability of the display device DD-a may be improved.

In a region of the first metal plate MP1a corresponding to the folding region FA, the holes OP may be defined. Unlike the embodiment according to the invention, when there is no support member below the region in which the holes OP of the first metal plate MP1a are disposed, or when a support member composed of a material with low restoration force is disposed, the region of the first metal plate MP1a in which the holes OP are disposed may sag caused by the weight.

Here, the adhesive layer ADL may not be disposed between a portion of the first metal plate MP1a which is adjacent to the grooves MP1-GV and the another portion of the second metal plate MP2a which corresponds to the flat surface MP1-FL of the first metal plate MP1a. Therefore, the first metal plate MP1a and the another portion of the second metal plate MP2a corresponding to the flat surface MP1-FL of the first metal plate MP1a may not be coupled to each other to be separable from each other along the thickness direction. During the folding operation of the electronic device EDE (see FIG. 2) as illustrated in FIG. 2, the flat surface MP1-FL of the first metal plate MP1a and the upper surface portion of the second metal plate MP2a which corresponds to the flat surface MP1-FL of the first metal plate MP1a may be spaced apart from each other.

The second metal plate MP2a may include an upper surface MP2-USa adjacent to (or closest to) the first metal plate MP1a. The upper surface MP2-USa of the second metal plate MP2a and the flat surface MP1-FL of the first metal plate MP1a may be disposed on the same plane, that is, effectively coplanar with each other. The upper surface MP2-USa of the second metal plate MP2a may be in direct contact with the adhesive layer ADL. The upper surface MP2-USa of the second metal plate MP2a and lower surface of the adhesive layer ADL may be disposed on the same plane.

Along the thickness direction of the display device DD-a, the thickness of the second metal plate MP2a may be, for example, about 50 micrometers (μm) to about 200 μm. In the above range, the display device DD-a may have an appropriate weight and an appropriate thickness, while the second metal plate MP2a may firmly support the portion of the first metal plate MP1a in which the holes OP are disposed.

The adhesive layer ADL may be disposed between non-folding areas of the first metal plate MP1a and the second metal plate MP2a. The adhesive layer ADL may be disposed in the groove MP1-GV of the first metal plate MP1a. The adhesive layer ADL may be disposed in the groove MP1-GV of the first metal plate MP1a, and may couple the first metal plate MP1a and the second metal plate MP2a to each other, in the non-folding area.

The adhesive layer ADL may not overlap the folding region FA on a plane. As not overlapping, elements may be adjacent to each other or spaced apart from each other in a direction along the plane. The adhesive layer ADL may include the first adhesive layer ADL1 overlapping the first non-folding region NFA1 on a plane, and the second adhesive layer ADL2 overlapping the second non-folding region NFA2 on a plane. The first adhesive layer ADL1 and the second adhesive layer ADL2 may be spaced apart from each other by a second width W2, which is larger than the first width W1, in the first direction DR1. The first adhesive layer ADL1 and the second adhesive layer ADL2 may be disconnected from each other by a second gap (e.g., the second width W2) for an entire length of the display module DM-a which is defined along the second direction DR2, without being limited thereto.

A recessed portion of the first metal plate MP1a in which the adhesive layer ADL is disposed may be defined as an adhesive portion ADA of the first metal plate MP1a. A boundary of the adhesive portion ADA may be defined by outer edges of the adhesive layer ADL. In addition, another portion of the first metal plate MP1a in which the adhesive layer ADL is not disposed may be defined as a non-adhesive portion NADA of the first metal plate MP1a. The non-adhesive portion NADA may include a remainder of the first support plate, except for the planar area corresponding to the adhesive layer ADL, without being limited thereto.

The adhesive portion ADA of the first metal plate MP1a may include a first adhesive portion ADA1 overlapping the first non-folding region NFA1 and defining a lower surface portion of the first metal plate MP1a, and a second adhesive portion ADA2 overlapping the second non-folding region NFA2 and defining a lower surface portion of the first metal plate MP1a. In the adhesive portion ADA, the first metal plate MP1a and the second metal plate MP2a may be coupled to each other, even when the display device DD-a is folded at the folding region FA. In the non-adhesive portion NADA, the first metal plate MP1a and the second metal plate MP2a may not be coupled to each other, even when the display device DD-a is folded at the folding region FA. Here, the first and second metal plates MP1a and MP2a may be separated and spaced apart from each other at respective facing surfaces thereof at the non-adhesive portion NADA.

The adhesive layer ADL may include a spacer particle SP and a thermosetting resin RS as a base material. Within the spacing adhesive layer, the spacer particle SP may serve to maintain a separation distance or gap uniform between a lower surface portion of the first metal plate MP1a and an upper surface portion of the second metal plate MP2a, at the groove MP1-GV of the first metal plate MP1a. The spacer particle SP may be applied without limitation as long as the particle is capable of maintaining the separation distance substantially unchanged. For example, the separation distance may be about 3 μm to about 12 μm. The diameter of the spacer particle SP may be, for example, about 3 μm to about 12 μm. The thickness of the adhesive layer ADL measured in the third direction DR3 may be, for example, about 3 μm to about 12 μm.

In a method of providing the display device DD-a, the adhesive layer ADL may be formed by applying a resin including the spacer particle SP and the thermosetting resin RS, followed by thermal-curing of the applied resin. For example, material for providing the adhesive layer ADL may be applied by an inkjet process. Alternatively, the material for providing the adhesive layer ADL may also be applied by a dispensing process. The adhesive layer ADL may be cured by bonding the second metal plate MP2a to the first metal plate MP1a, followed by heating.

Hereinafter, in the present disclosure, the “thickness” may refer to a value measured in the third direction DR3 (e.g., a thickness direction).

The thickness of the panel protection layer PF may be smaller than the thickness of the window protection layer WPL, and the thickness of the barrier layer BL may be smaller than the thickness of the panel protection layer PF. The thickness of the display panel DP may be smaller than the thickness of the barrier layer BL, and may be the same as the thickness of the window WIN. The thickness of the impact absorption layer DL may be smaller than the thickness of the display panel DP.

The thickness of the first adhesive layer AL1 may be the same as the thickness of the barrier layer BL, and the thickness of each of the second adhesive layer AL2 and the third adhesive layer AL3 may be the same as the thickness of the panel protection layer PF. The thickness of the fourth adhesive layer AL4 may be the same as the thickness of the fifth adhesive layer AL5. The thickness of each of the fourth adhesive layer AL4 and the fifth adhesive layer AL5 may be smaller than the thickness of the display panel DP, and may be larger than the thickness of the impact absorption layer DL. The thickness of the sixth adhesive layer AL6 may be smaller than the thickness of the impact absorption layer DL. The thickness of a hard coating layer HC may be smaller than the thickness of the sixth adhesive layer AL6.

Referring to FIG. 7B, the first metal plate MP1a may include a plurality of holes OP in the folding region FA. The holes OP may be defined as openings or hole patterns. The holes OP may be disposed in the form of penetrating the first metal plate MP1a in the third direction DR3. The holes OP may be formed through a laser process or a microblasting process.

The holes OP may be arranged according to a predetermined rule, in one or more directions along the plane defined by the first and second directions DR1 and DR2 crossing each other. The holes OP may be arranged in a lattice form, and may form a lattice pattern in the folding region FA. The lattice may be defined by the holes OP together with solid portions of the first metal plate MP1a spaced apart from each other by the holes OP. The first metal plate MP1a at the non-folding area may having only a material (solid) portion and may exclude the holes OP.

Since the holes OP are defined in a folding area portion of the first metal plate MP1a, the planar area of material portions of the first metal plate MP1a which correspond to the folding region FA may be reduced, so that the rigidity of the first metal plate MP1a at the folding region FA may be lowered. Therefore, compared to a case in which the holes OP are not defined on the first metal plate MP1a, when the holes OP are defined therein, the flexibility of the first metal plate MP1a at the folding region FA may be increased. As a result, the first metal plate MP1a may be easily folded at the folding region FA.

Referring to FIG. 7C, the holes OP may include a plurality of first holes OP1 and a plurality of second holes OP2. The plurality of first holes OP1 may be arranged spaced apart from each other along the second direction DR2, such as along a first virtual line. The plurality of second holes OP2 may be arranged spaced apart from each other along the second direction DR2, such as along a second virtual line adjacent to the first virtual line. The first holes OP1 and the second holes OP2 may be alternately arranged along the first direction DR1. The first holes OP1 and the second holes OP2 may be arranged shifted from each other in the second direction DR2, such as to be staggered.

The first metal plate MP1a corresponding to the folding region FA may include first branch portions BR1 as material (solid) portions disposed between the first holes OP1, or between the second holes OP2. The first branch portions BR1 may be disposed between the first holes OP1 adjacent to each other in the second direction DR2, or between the second holes OP2 adjacent to each other in the second direction DR2. The first metal plate MP1a corresponding to the folding region FA may include second branch portions BR2 disposed between the first holes OP1 and the second holes OP2. The second branch portions BR2 may be disposed between the first holes OP1 and the second holes OP2 adjacent to each other in the first direction DR1. The first and second branch portions BR1 and BR2 may intersect each other.

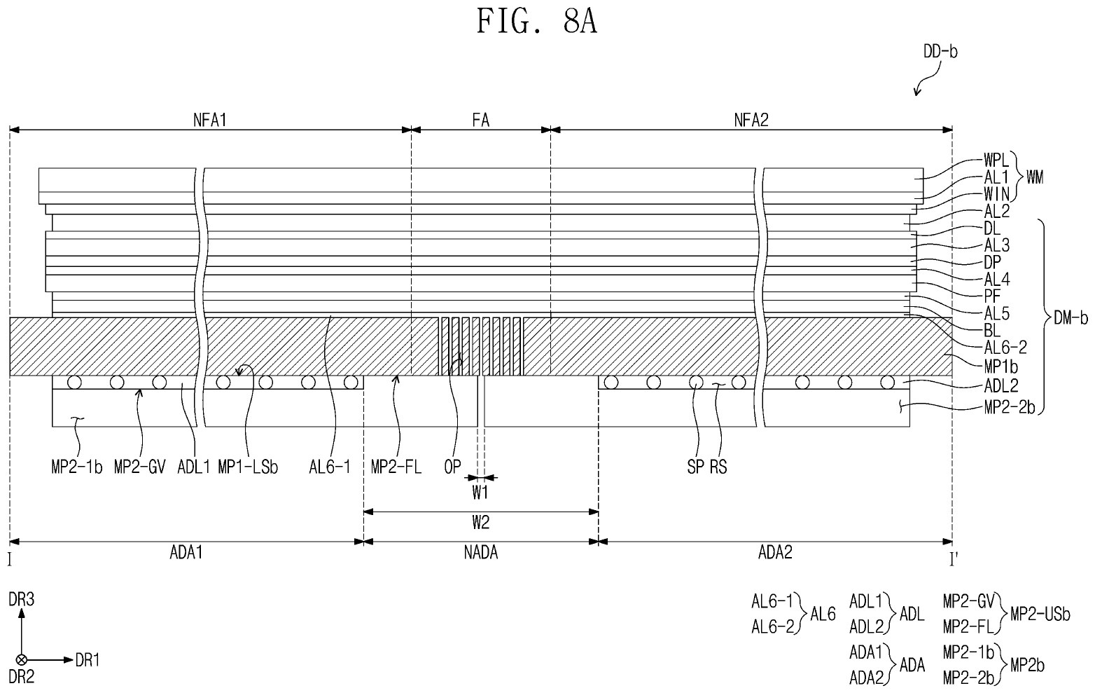

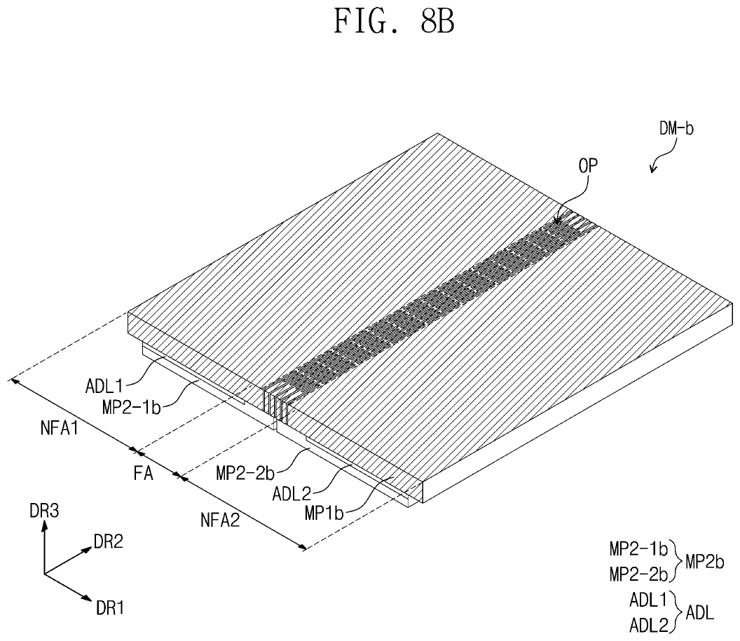

FIG. 8A is a cross-sectional view of a display device DD-b according to an embodiment of the invention. FIG. 8B is a perspective view of some components of a display module DM-b according to an embodiment of the invention.

FIG. 8A is an embodiment of a cross-section corresponding line I-I′ of the display device DD of FIG. 3. FIG. 8B is a perspective view exemplarily illustrating some components of the display module DM-b of FIG. 8A.

The same descriptions as those described above with reference to FIG. 7A to FIG. 7C may be equally applied to FIG. 8A and FIG. 8B, except for the disposition relationship between the first metal plate MP1a and the second metal plate MP2a and the adhesive layer ADL.

A first metal plate MP1b may be disposed below a display panel DP. For example, the first metal plate MP1b may be disposed below a barrier layer BL. The first metal plate MP1b may be coupled to the barrier layer BL by a sixth adhesive layer AL6. The sixth adhesive layer AL6 may include a 6-1 adhesive layer AL6-1 and a 6-2 adhesive layer AL6-2 spaced apart from the 6-1 adhesive layer AL6-1 in the first direction. The 6-1 adhesive layer AL6-1 may couple a barrier layer BL overlapping a first non-folding region NFA1 and the first metal plate MP1b, and the 6-2 adhesive layer AL6-2 may couple a barrier layer BL overlapping a second non-folding region NFA2 and the first metal plate MP1b.

The first metal plate MP1b may be disposed below the display panel DP and support the display panel DP. The first metal plate MP1b may be defined as a first support plate.

The first metal plate MP1b includes a metal material. The first metal plate MP1b may include a metal material having a high modulus. For example, the first metal plate MP1b may include stainless steel. Therefore, the supporting force of the first metal plate MP1b supporting the display panel DP may be improved. In addition, the deformation of a portion in which holes OP of the first metal plate MP1b corresponding to a folding region FA are defined may also be prevented.

The first metal plate MP1b may include a lower surface MP1-LSb adjacent to a second metal plate MP2b to be described later. The lower surface MP1-LSb of the first metal plate MP1b may be a flat surface. The first metal plate MP1b may include an adhesive portion ADA overlapping an adhesive layer ADL to be described later, and a non-adhesive portion NADA not overlapping the adhesive layer ADL.

The second metal plate MP2b may be disposed below the first metal plate MP1b. The second metal plate MP2b may include a 2-1 metal plate MP2-1b and a 2-2 metal plate MP2-2b. The 2-1 metal plate MP2-1b may overlap the first non-folding region NFA1, and the 2-2 metal plate MP2-2b may overlap the second non-folding region NFA2. The 2-1 metal plate MP2-1b and the 2-2 metal plate MP2-2b may be disposed spaced apart by a first width W1 in the first direction DR1.

The second metal plate MP2b may include an upper surface MP2-USb adjacent to the first metal plate MP1b. On the upper surface MP2-USb of the second metal plate MP2b, a groove MP2-GV, and a flat surface MP2-FL may be defined. Specifically, along the upper surface MP2-USb of the second metal plate MP2b, the grooves MP2-GV overlapping the first non-folding region NFA1 and the second non-folding region NFA2 may be defined open to the first support plate. In addition, along the upper surface MP2-USb of the second metal plate MP2b, the flat surface MP2-FL overlapping the folding region FA may be defined adjacent to the grooves MP2-GV. The grooves MP2-GV may be formed by an etching process.

In the groove MP2-GV defined recessed from a plane of the upper surface MP2-USb of the second metal plate MP2b, the adhesive layer ADL to be described later may be disposed. The adhesive layer ADL may include a first adhesive layer ADL1 and a second adhesive layer ADL2. The first adhesive layer ADL1 may be disposed in a groove MP2-GV of the second metal plate MP2b overlapping the first non-folding region NFA1, and the second adhesive layer ADL2 may be disposed in a groove MP2-GV of the second metal plate MP2b overlapping the second non-folding region NFA2.

Since the second metal plate MP2b includes the groove MP2-GV and the adhesive layer ADL is disposed in the groove MP2-GV, there may be no separation or step between the first metal plate MP1b corresponding to the folding region FA and the second metal plate MP2b.

A portion of the first metal plate MP1b corresponding to the groove MP2-GV of the second metal plate MP2b on a plane may be disposed above the second metal plate MP2b with the adhesive layer ADL interposed therebetween. The portion of the first metal plate MP1b corresponding to the groove MP2-GV of the second metal plate MP2b may be coupled to the second metal plate MP2b through the adhesive layer ADL. Specifically, the 2-1 metal plate MP2-1b may be coupled to the first metal plate MP1b through the first adhesive layer ADL1 disposed in the first non-folding region NFA1, and the 2-2 metal plate MP2-2b may be coupled to the first metal plate MP1b through the second adhesive layer ADL2 disposed in the second non-folding region NFA2.

The second metal plate MP2b overlapping the folding region FA on a plane may be directly disposed below the first metal plate MP1b. Specifically, another portion of the first metal plate MP1b corresponding to the flat surface MP2-FL of the second metal plate MP2b on a plane may be directly disposed on the second metal plate MP2b. Since the another portion of the first metal plate MP1b is directly disposed on the flat surface MP2-FL of the second metal plate MP2b, the first metal plate MP1b of the folding region FA may be supported without deformation such as sagging.

In addition, since the deformation of the first metal plate MP1b of the folding region FA is prevented, deformation of the display panel DP disposed in an upper portion of the first metal plate MP1b or a folding region FA of a window WIN may also be prevented. That is, the folding reliability of the display device DD-b may be improved.

In a region of the first metal plate MP1b corresponding to the folding region FA, the holes OP may be disposed. Unlike the embodiment according to the invention, when there is no support member below the region in which the holes OP of the first metal plate MP1b are disposed, or when a support member composed of a material with low restoration force is disposed, the region in which the holes OP of the first metal plate MP1b are disposed may sag caused by the weight.

Here, the adhesive layer ADL may not be disposed between the first metal plate MP1b and the flat surface MP2-FL of the second metal plate MP2b. Therefore, the first metal plate MP1b and the flat surface MP2-FL of the second metal plate MP2b may not be coupled to each other (e.g., may be separable from each other). During the folding operation of the electronic device EDE (see FIG. 2) as illustrated in FIG. 2, the first metal plate MP1b and the flat surface MP2-FL of the second metal plate MP2b may be spaced apart from each other.

The first portion of the lower surface MP1-LSb of the first metal plate MP1b and the flat surface MP2-FL of the second metal plate MP2b may be disposed on the same plane. The second portion of lower surface MP1-LSb of the first metal plate MP1b may be in direct contact with the adhesive layer ADL.

The adhesive layer ADL may be disposed between the first metal plate MP1b and the second metal plate MP2b. The adhesive layer ADL may be disposed in the groove MP2-GV of the second metal plate MP2b. The adhesive layer ADL may be disposed in the groove MP2-GV of the second metal plate MP2b, and may couple the first metal plate MP1b and the second metal plate MP2b.

The adhesive layer ADL may include a spacer particle SP and a thermosetting resin RS. The spacer particle SP may serve to maintain a separation distance uniform between the first metal plate MP1b and the second metal plate MP2b due to the groove MP2-GV of the second metal plate MP2b.

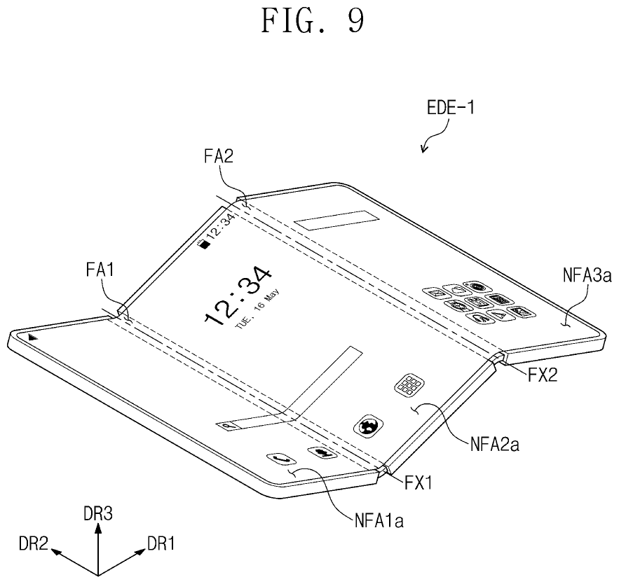

FIG. 9 is a perspective view of an electronic device EDE-1 according to an embodiment of the invention.

The same contents described above with reference to FIG. 1 to FIG. 8B may be applied to the electronic device EDE-1 illustrated in FIG. 9.

Referring to FIG. 9, the electronic device EDE-1 may include folding regions FA1 and FA2, and a plurality of non-folding regions NFA1a, NFA2a, and NFA3a. The folding regions FA1 and FA2 may include a first folding region FA1 and a second folding region FA2 corresponding to different folding axes. The non-folding regions NFA1a, NFA2a, and NFA3a may include a first non-folding region NFA1a, a second non-folding region NFA2a, and a third non-folding region NFA3a.

The first folding region FA1 may be folded with respect to a first folding axis FX1, such that the first non-folding region NFA1a and the second non-folding region NFA2a may face each other. The second folding region FA2 may be folded with respect to a second folding axis FX2 such that the second non-folding region NFA2a and the third non-folding region NFA3a may oppose each other. Therefore, in a state in which the electronic device EDE-1 is completely folded, the first non-folding region NFA1a and the second non-folding region NFA2a may face each other, which may be referred to as in-folding, together with the second non-folding region NFA2a and the third non-folding region NFA3a opposing each other.

In a state in which the electronic device EDE-1 is completely folded, the third non-folding region NFA3a may be exposed to the outside, which may be referred to as out-folding. Since the first folding region FA1 is in-folded, and the second folding region FA2 is out-folded, the radius of curvature of the electronic device EDE-1 at the first folding region FA1 may be smaller than the radius of curvature of the electronic device EDE-1 at the second folding region FA2. The radii of curvature of the electronic device EDE-1 may be defined with respect to the same plane.

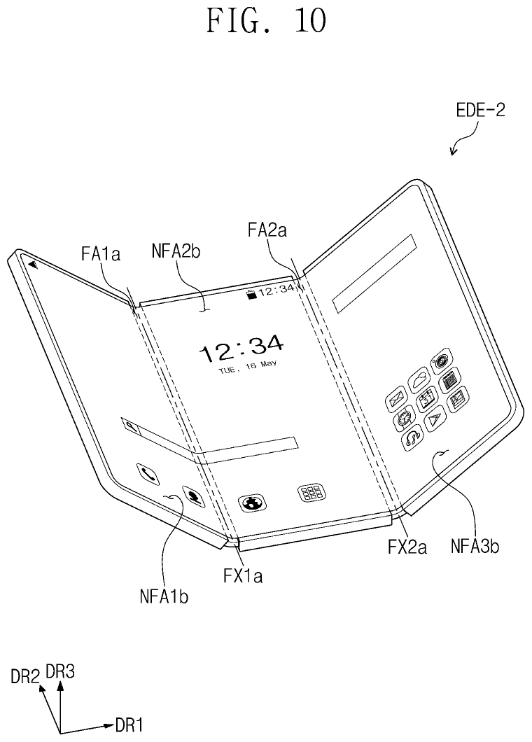

FIG. 10 is a perspective view of an electronic device EDE-2 according to an embodiment of the invention.

The same contents described above with reference to FIG. 1 to FIG. 8B may be applied to the electronic device EDE-2 illustrated in FIG. 10.

Referring to FIG. 10, the electronic device EDE-2 may include folding regions FA1a and FA2a, and a plurality of non-folding regions NFA1b, NFA2b, and NFA3b. The folding regions FA1a and FA2a may include a first folding region FA1a and a second folding region FA2a. The non-folding regions NFA1b, NFA2b, and NFA3b may include a first non-folding region NFA1b, a second non-folding region NFA2b, and a third non-folding region NFA3b.

The first folding region FA1a may be folded with respect to a first folding axis FX1a. The second folding region FA2a may be folded with respect to a second folding axis FX2a. For example, both the first folding region layer FA1a and the second folding region layer FA2a may be in-folded. Therefore, in a state in which the electronic device EDE-2 is completely folded, the first non-folding region NFA1b and the third non-folding region NFA3b may overlap the second non-folding region NFA2b. In another embodiment of the invention, both the first folding region FA1a and the second folding region FA2a may be out-folded for which the first non-folding region NFA1b and the third non-folding region NFA3b may overlap the second non-folding region NFA2b.

According to the above description, a display device DD according to the invention has improved folding reliability since a second metal plate MP2a (e.g., a second support plate) is directly disposed at a lower portion of a folding region of a first metal plate MP1a (e.g., a first support plate), and has improved surface quality since an adhesive layer ADL between the first metal plate MP1a and the second metal plate MP2a includes a spacer within the adhesive patterns of the adhesive layer ADL to maintain a spacing between the first and second support plates, even in the display device DD which is folded at the folding area.

In an embodiment, a display device includes a display panel including a non-folding region and a folding region adjacent to each other along a first direction, a first metal plate overlapping the folding region and in which holes are defined overlapping the folding region, a second metal plate overlapping the folding region and facing the display panel with the holes of the first metal plate therebetween, the first metal plate including a lower surface adjacent to the second metal plate, the second metal plate including an upper surface adjacent to the first metal plate, and an adhesive layer which is between the first metal plate and the second metal plate. A groove is defined recessed in the lower surface of the first metal plate and open to the second metal plate or recessed in the upper surface of the second metal plate and open to the first metal plate. The adhesive layer is in the groove.

At the folding region, the second metal plate may be directly below the first metal plate.

The second metal plate may include a 2-1 metal plate overlapping the first non-folding region, and a 2-2 metal plate which overlaps the second non-folding region and is spaced apart from the 2-1 metal plate by a first width defined along the first direction.

The groove may be defined in plural including a first groove at the first non-folding region and a second groove at the second non-folding region. The adhesive layer may include a first adhesive layer which overlaps the first non-folding region and is spaced apart from the folding region along the first direction, and a second adhesive layer which overlaps the second non-folding region, is spaced apart from the folding region along the first direction and from the first adhesive layer by a second width defined along the first direction, the second width being larger than the first width by which the 2-2 metal plate is spaced apart from the 2-1 metal plate.

The adhesive layer may include a spacer and a resin.

Referring to FIGS. 7A and 7B, for example the first metal plate may define the groove MP1-GV which overlaps the non-folding region and is recessed from the lower surface of the first metal plate, and a flat surface MP1-FL of the lower surface which is adjacent to the groove along the first direction and overlaps the folding region. Here, a portion of the second metal plate MP2a which overlaps the groove defined in the first metal plate MP1a faces a thickness portion of the first metal plate with the adhesive layer ADL interposed therebetween, and a portion of the second metal plate MP2a which overlaps the flat surface of the first metal plate MP1a is directly below the flat surface of the first metal plate.

Referring to FIGS. 8A and 8B, for example, the second metal plate MP2b may define the groove MP2-GV which overlaps the non-folding region and is recessed from the upper surface of the second metal plate MP2b, and a flat surface MP2-FL of the upper surface which is adjacent to the groove along the first direction and overlaps the folding region. Here, a portion of the first metal plate MP1b which overlaps the groove defined in the second metal plate MP2b faces a thickness portion of the second metal plate MP2b with the adhesive layer interposed therebetween, and a portion of the first metal plate which overlaps the flat surface of the second metal plate is directly above the flat surface of the second metal plate.

In an embodiment, a display device includes a display panel including a non-folding region and a folding region adjacent to each other along a first direction, a first metal plate overlapping the folding region and in which holes are defined overlapping the folding region, a second metal plate overlapping the folding region and facing the display panel with the holes of the first metal plate therebetween, and an adhesive layer between the first metal plate and the second metal plate. The first metal plate includes at the non-folding region, an adhesive area at which the first metal plate is bonded to the second metal plate by the adhesive layer, at the folding region, a non-adhesive area which is adjacent to the adhesive area along the first direction and at which the first metal plate is unbonded to the second metal, and the non-adhesive area directly above the second metal plate.

Although the invention has been described with reference to embodiments of the invention, it will be understood by those skilled in the art that various modifications and changes in form and details may be made therein without departing from the spirit and scope of the invention as set forth in the following claims. Accordingly, the technical scope of the invention is not intended to be limited to the contents set forth in the detailed description of the specification, but is intended to be defined by the appended claims.

What is claimed is:

1. A display device comprising:
a display panel including a first non-folding region, a folding region, and a second non-folding region which are sequentially arranged along a first direction;
a first metal plate including a plurality of holes overlapping the folding region on a plane, and disposed below the display panel;
a second metal plate disposed below the first metal plate; and
an adhesive layer disposed between the first metal plate and the second metal plate,
wherein:
the first metal plate includes a lower surface adjacent to the second metal plate; and
the second metal plate includes an upper surface adjacent to the first metal plate,
wherein at least one of the lower surface of the first metal plate or the upper surface of the second metal plate includes grooves overlapping the first non-folding region and the second non-folding region on a plane,
wherein the adhesive layer is disposed in the grooves.

2. The display device of claim 1, wherein the second metal plate overlapping the folding region on a plane is directly disposed below the first metal plate.

3. The display device of claim 1, wherein the second metal plate comprises a 2-1 metal plate overlapping the first non-folding region on a plane, and a 2-2 metal plate overlapping the second non-folding region on a plane, wherein the 2-1 metal plate and the 2-2 metal plate are spaced apart by a first width in the first direction.

4. The display device of claim 3, wherein:
the adhesive layer does not overlap the folding region on a plane; and
the adhesive layer comprises a first adhesive layer overlapping the first non-folding region on a plane, and a second adhesive layer overlapping the second non-folding region on a plane, wherein the first adhesive layer and the second adhesive layer are spaced apart by a second width, which is larger than the first width, in the first direction.

5. The display device of claim 1, wherein the adhesive layer comprises a spacer particle and a thermosetting resin.

6. The display device of claim 1, wherein the lower surface of the first metal plate comprises the grooves, and a flat surface on which the grooves are not disposed.

7. The display device of claim 6, wherein:
a portion of the second metal plate overlapping the grooves of the first metal plate on a plane is disposed below the first metal plate with the adhesive layer interposed therebetween; and
another portion of the second metal plate overlapping the flat surface of the first metal plate on a plane is directly disposed below the first metal plate.

8. The display device of claim 1, wherein the upper surface of the second metal plate comprises the grooves, and a flat surface on which the grooves are not disposed.

9. The display device of claim 8, wherein:
a portion of the first metal plate overlapping the grooves of the second metal plate on a plane is disposed above the second metal plate with the adhesive layer interposed therebetween; and
another portion of the first metal plate overlapping the flat surface of the second metal plate on a plane is directly disposed above the second metal plate.

10. The display device of claim 1, further comprising a window disposed above the display panel.

11. A display device comprising:
a display panel including a first non-folding region, a folding region, and a second non-folding region which are sequentially arranged along a first direction;
a first metal plate including a plurality of holes overlapping the folding region on a plane, and disposed below the display panel;
a second metal plate disposed below the first metal plate; and
an adhesive layer disposed between the first metal plate and the second metal plate,
wherein
the first metal plate includes an adhesive portion overlapping the first non-folding region and the second non-folding region on a plane, and a non-adhesive portion overlapping the folding region on a plane; and
the non-adhesive portion of the first metal plate is directly disposed above the second metal plate, and the adhesive portion of the first metal plate is disposed above the second metal plate with the adhesive later interposed therebetween.

12. The display device of claim 11, wherein the second metal plate comprises a 2-1 metal plate overlapping the first non-folding region on a plane, and a 2-2 metal plate overlapping the second non-folding region on a plane,
wherein the 2-1 metal plate and the 2-2 metal plate are spaced apart by a first width in the first direction.

13. The display device of claim 12, wherein:
the adhesive layer does not overlap the folding region on a plane; and
the adhesive layer comprises a first adhesive layer overlapping the first non-folding region on a plane, and a second adhesive layer overlapping the second non-folding region on a plane, wherein the first adhesive layer and the second adhesive layer are spaced apart by a second width, which is larger than the first width, in the first direction.

14. The display device of claim 11, wherein the adhesive layer comprises a spacer particle and a thermosetting resin.

15. The display device of claim 11, wherein the first metal plate comprises a lower surface adjacent to the second metal plate,
a groove is defined on the lower surface corresponding to the adhesive portion of the first metal plate, and
the adhesive layer is disposed in the groove of the first metal plate.

16. The display device of claim 15, wherein a flat substrate is defined on the lower surface corresponding to the non-adhesive portion of the first metal plate.

17. The display device of claim 16, wherein on the adhesive layer, a lower surface in contact with the second metal plate is defined,
wherein the flat surface of the first metal plate and the lower surface of the adhesive layer are disposed on the same plane.

18. The display device of claim 11, wherein the second metal plate comprises an upper surface adjacent to the first metal plate,
a groove is defined on the upper surface of the second metal plate corresponding to the adhesive portion of the first metal plate on a plane, and
the adhesive layer is disposed in the groove of the second metal plate.

19. The display device of claim 18, wherein a flat surface is defined on the upper surface of the second metal plate corresponding to the non-adhesive portion of the first metal plate on a plane.

20. The display device of claim 19, wherein on the adhesive layer, an upper surface in contact with the first metal plate is defined, wherein the flat surface of the second metal plate and the upper surface of the adhesive layer are disposed on the same plane.
